(19) United States
(12) Patent Application Publication
(10) Pub. No.: US 2025/0205758 A1
(43) Pub. Date: Jun. 26, 2025

(54) CLEANING APPARATUS, IMPRINT APPARATUS, CLEANING METHOD, AND ARTICLE MANUFACTURING METHOD

(71) Applicant: CANON KABUSHIKI KAISHA, Tokyo (JP)

(72) Inventor: HIROYUKI MARUYAMA, Tochigi (JP)

(21) Appl. No.: 18/973,738

(22) Filed: Dec. 9, 2024

(30) Foreign Application Priority Data
Dec. 22, 2023 (JP) 2023-216686

(51) Int. Cl. B08B 7/00; B08B 13/00; B08B 15/04; G01N 15/00; G03F 7/00

(52) U.S. Cl. CPC B08B 7/0035; B08B 13/00; B08B 15/04; G03F 7/0002; G01N 15/00

(57) ABSTRACT

A cleaning apparatus for cleaning an original with plasma includes a stage for holding the original, a plasma irradiating portion for irradiating plasma, a driving unit for adjusting a relative position of the stage and the plasma irradiating portion, and a controlling unit configured to control the plasma irradiating portion and the driving unit to start an irradiation of the plasma when a pattern portion included in the original and the plasma irradiating portion do not face each other.

### BACKGROUND OF THE INVENTION

### Field of the Invention

The present invention relates to a cleaning apparatus, an imprint apparatus, a cleaning method, and an article manufacturing method.

### Description of the Related Art

With the demand for miniaturization of semiconductor devices, in addition to the conventional photolithography technology, an imprint technology of molding an uncured resin (imprint material) on a substrate with a mold and forming a fine pattern of the resin on the substrate has attracted attention. In the imprint technology, a fine structure on the order of nanometers can be formed on a substrate.

In the imprint apparatus, first, a resin is supplied (applied) to an imprint region on a substrate, the resin is cured by irradiating light in a state where an uncured resin on the substrate and a mold are in contact with each other, and a pattern is formed on the substrate by separating the mold from the cured resin.

In the imprint apparatus, since the mold and the resin on the substrate are brought into contact with each other, a cured product of the resin may remain in the mold. When the imprint process is performed in a state where the cured product of the resin remains in the mold, the remaining resin is transferred as it is, and a defect or the like occurs in the pattern formed on the substrate. Therefore, the mold needs to be periodically cleaned.

Japanese Patent Application Laid-Open No. 2009-16434 discloses a technique for removing a foreign matter by plasma. Japanese Patent Application Laid-Open No. 2010-93245 discloses a technique in which a cleaning apparatus for cleaning a member to be cleaned with plasma is provided in an exposure apparatus. Japanese Patent Application Laid-Open No. 2021-506119 discloses a technique in which an exhaust opening, a heat radiation opening portion of a heater, an opening portion of plasma irradiation, and a gas discharge opening portion are arranged with their centers aligned side by side in a plasma head, and the foreign matter adhering to a substrate is removed by plasma.

However, in the conventional cleaning apparatus, there is a problem that fine particles generated from an electrode or a dielectric body formed in a plasma irradiating portion at the start of plasma irradiation adhere to the surface of a substrate to be cleaned or a constituent member of the cleaning apparatus.

### SUMMARY OF THE INVENTION

Therefore, the present invention provides a cleaning apparatus which is beneficial for cleaning an original used for transferring a pattern onto a substrate.

According to an aspect of the present invention, a cleaning apparatus for cleaning an original with plasma, includes: a stage for holding the original; a plasma irradiating portion for irradiating plasma; a driving unit for adjusting a relative position of the stage and the plasma irradiating portion; and a controlling unit configured to control the plasma irradiating portion and the driving unit to start an irradiation of the plasma when a pattern portion included in the original and the plasma irradiating portion do not face each other.

According to the present invention, it is possible to provide a cleaning apparatus which is beneficial for cleaning an original used for transferring a pattern onto a substrate.

Further features of the present invention will become apparent from the following description of exemplary embodiments with reference to the attached drawings.

### BRIEF DESCRIPTION OF THE DRAWINGS

FIG. 1 is a schematic cross-sectional view illustrating a configuration of a cleaning apparatus according to a first embodiment.

FIG. 2 is a schematic top view of the cleaning apparatus according to the first embodiment.

FIG. 3 is a flowchart showing a cleaning method according to the first embodiment.

FIG. 4 is a schematic cross-sectional view illustrating a configuration of a cleaning apparatus according to a second embodiment.

FIG. 5 is a flowchart showing a cleaning method according to the second embodiment.

FIG. 6 is a flowchart showing a cleaning method according to the second embodiment.

FIG. 7 is a schematic diagram illustrating a configuration of an imprint apparatus to which a cleaning apparatus is applied.

### DESCRIPTION OF THE EMBODIMENTS

Hereinafter, preferred embodiments of the present invention will be described with reference to the accompanying drawings. In the drawings, the same reference numerals denote the same members or elements, and a repetitive description thereof will not be given. In the present embodiment, an example in which the present invention is applied to a mold (original) used in an imprint apparatus that forms a pattern on an imprint material on a substrate will be described, but the present invention may be applied to a mask (original) used in an exposure apparatus that projects and transfers a pattern onto a substrate. As described above, the original in the present invention includes a mold used in an imprint apparatus and a mask used in an exposure apparatus.

### First Embodiment

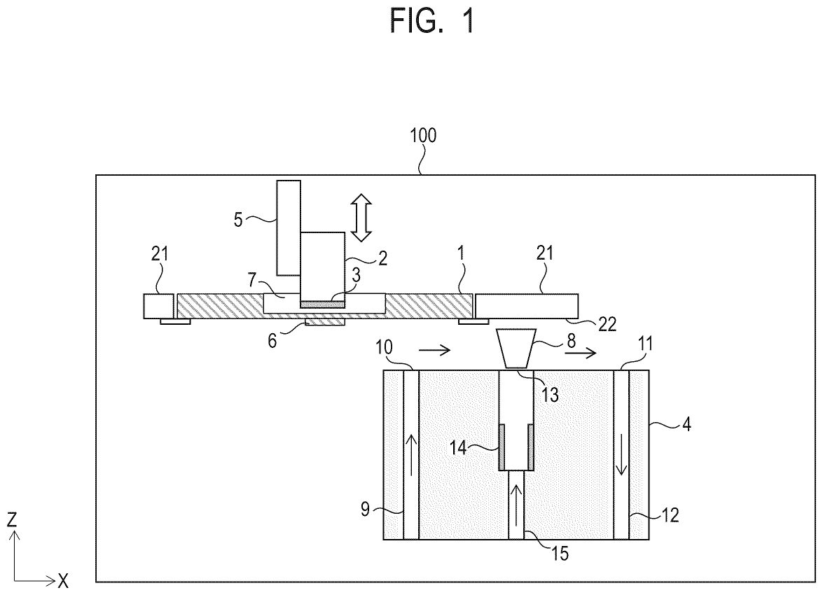

FIG. 1 is a schematic diagram illustrating a configuration of a cleaning apparatus 100 according to a first embodiment.

In the following drawings, directions orthogonal to each other in a plane parallel to the surface of the mold are defined as an X direction and a Y direction, and a direction perpendicular to the X direction and the Y direction (a direction perpendicular to the surface of the mold) is defined as a Z direction. The cleaning apparatus 100 includes a mold stage 21 that holds the mold 1, a heating unit 2, a heat radiation portion 3 of the heating unit 2, and a plasma head 4. The heating unit 2 is held and driven by the driving mechanism 5.

The mold 1 is used, for example, in an imprint apparatus that forms a pattern of an imprint material on a substrate. One surface of the mold 1 is provided with a pattern portion 6 in which a concavo-convex pattern for molding the imprint material supplied onto the substrate is formed in a three-dimensional shape. The pattern portion 6 is also called as a mesa, and is formed in convex portions of several tens of micrometers to several hundred micrometers so that portions other than the pattern portion 6 of the mold 1 do not come into contact with the substrate at the time of mold-pressing. Therefore, a cured product of the imprint material is likely to remain at an end portion of the pattern portion 6 called a mesa edge, and the cured product of the imprint material may be deposited when the imprint process is repeated.

A core-out portion 7 (recess) which is hollowed out in a cylindrical shape is formed in a central portion of the opposing surface side of the pattern portion 6 of the mold 1 of the present embodiment. The core-out portion 7 is formed in a region corresponding to the concave-convex pattern portion 6, and more specifically, is a recess having a larger area than the concave-convex pattern portion 6.

The heat radiation portion 3 of the heating unit 2 is formed of, for example, a far-infrared heater. In the imprint apparatus employing the photocuring method, quartz is used as a material of the mold 1 and has a transmittance of 90% or more with respect to light having a wavelength of 0.2 μm to 2 μm. Quartz has low transmittance and easily absorbs heat in a region of far infrared rays having a wavelength of 3 μm or more, and thus can be efficiently heated.

The speed of the chemical reaction between the radicals generated in the plasma 8 irradiated from the plasma head 4 and the cured product of the imprint material can be increased by raising the temperature of the pattern portion 6, thereby increasing the cleaning efficiency of the pattern portion 6.

To prevent particles contained in the gas generated by the chemical reaction of the plasma 8 from being attached again to the pattern portion 6, it is desirable to keep the temperature of the pattern portion 6 at a high temperature. Therefore, it is desirable that the heat radiation portion 3 be disposed directly above the pattern portion 6, and the size of the heat radiation portion 3 be the same as or larger than that of the pattern portion 6. When the mold 1 is transported into the cleaning apparatus 100 and mounted on the mold stage 21, the heating unit 2 is raised in the Z direction by the driving mechanism 5 and retracted so as not to come into contact with the mold 1. After the mold 1 is mounted on the mold stage 21, the heating unit 2 may be lowered in the Z direction, the heat radiation portion 3 may be disposed in the core-out portion 7 of the mold 1, and the distance between the lower surface of the heat radiation portion 3 and the bottom surface of the core-out portion 7 may be controlled by a controlling unit (not shown) to be preferably between 0.1 mm and 2 mm.

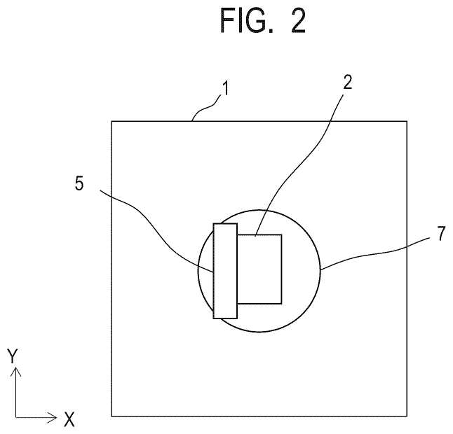

FIG. 2 is a top view of the cleaning apparatus of FIG. 1. The heating unit 2 is disposed substantially at the center of the core-out portion 7 of the mold 1, and is held by the driving mechanism 5. The heating unit 2 is smaller than the recessed shape of the core-out portion 7, and can be driven so that the lower surface of the heat radiation portion 3 is close to the bottom surface of the core-out portion 7. A measuring device (not shown) for measuring the positions and shapes of the mold 1 and the core-out portion 7 may be provided.

Returning to FIG. 1, the plasma 8 irradiated from the plasma head 4 is, for example, atmospheric pressure plasma 8 generated in atmospheric pressure using a high frequency power source. Cost can be reduced by using the atmospheric pressure plasma. When the plasma 8 is surrounded by the atmosphere, various gas phase reactions occur, and unevenness in cleaning of the pattern portion 6 occurs. In order to suppress the occurrence of unevenness, it is desirable to purge the periphery of the plasma 8 with an inert gas.

The purge gas passes through the gas passage 9 and is discharged from the purge gas discharge opening 10. The purge gas flows on the upper surface of the plasma head 4, passes through the plasma irradiating portion 13, and is recovered from the gas exhaust opening 11 through the gas flow path 12. The harmful gas component of the purge gas may be treated by a detoxifying device (not shown).

An electrode 14 is provided in the plasma irradiating portion 13, and plasma 8 is generated by applying a high-frequency voltage to the electrode 14. A first gas for generating the plasma 8 and a second gas containing a reactant are supplied through the gas flow path 15. The first gas and the second gas are recovered from the gas exhaust opening 11 through the gas flow path 12. The electrode 14 may have a parallel plate type structure or a torch type structure having a cylindrical structure, covered with a dielectric, but is not limited thereto, and may have any structure as long as plasma 8 is generated. The plasma head 4 may include one or a plurality of plasma irradiating portions 13 that irradiate the plasma 8.

At least one of the mold stage 21 holding the mold 1 and the plasma head 4 is configured to be relatively movable in the XY plane by a driving unit (not shown), so that the relative positional relationship between the mold 1 and the plasma head 4 can be changed. When the range in which the plasma 8 is irradiated to the mold 1 is narrow with respect to the region of the pattern portion 6, at least one of the mold stage 21 holding the mold 1 and the plasma head 4 in the XY plane is moved so that the entire pattern portion 6 can be cleaned.

Further, the degree of contamination of the pattern portion 6 due to adhesion of foreign matter may be detected by a detection mechanism (not shown) or the like, and at least one of the mold stage 21 and the plasma head 4 may be driven while changing the moving speed or the moving range according to the degree of contamination. The movement on the XY plane may be only one-axis movement or two-axis movement. Alternatively, the cleaning time may be shortened by performing the cleaning only at the portion where the foreign matter is attached in the pattern portion 6. Alternatively, the cleaning may be performed on the foreign matter adhering to the mold 1 including the pattern portion 6.

The heating unit 2 held by the driving mechanism 5 may be driven in the Z direction so as not to come into contact with the side surface of the core-out portion 7 in accordance with the driving of the mold stage 21. Alternatively, the driving mechanism 5 may move in the XY plane in accordance with the movement of the mold stage 21.

According to the present embodiment, even when the irradiation range of the plasma 8 is narrow with respect to the pattern portion 6, it is possible to efficiently remove the foreign matter such as the imprint material deposited on the mold 1 by changing the relative positional relationship between the mold 1 and the plasma head 4. In addition, according to the present embodiment, it is possible to efficiently remove foreign matter such as the imprint material deposited on the mold 1 by irradiating the plasma 8 in a state where the temperature of the pattern portion 6 is maintained at a high temperature.

In a case of a method in which plasma is generated by arc discharge of the electrode 14 at the start of irradiation of the plasma 8, the electrode material is discharged as particles from the surface of the electrode 14 together with the plasma 8 from the plasma irradiating portion 13 by the arc discharge. In addition, in a case of dielectric barrier discharge, the dielectric material is discharged as particles together with the plasma 8 from the plasma irradiating portion 13. Therefore, when the irradiation of the plasma 8 is started in a state where the plasma irradiating portion 13 is located below the mold 1 (the mold 1 is located in the plasma irradiation direction), particles of the electrode material or the dielectric material discharged together with the plasma 8 may adhere to the mold 1.

In the cleaning apparatus of the present embodiment, to prevent particles of the electrode material or the dielectric material from adhering to the mold 1, the irradiation of the plasma 8 is started in a state where the lower surface 22 of the mold stage 21 (other than the original) is located above the plasma irradiating portion 13.

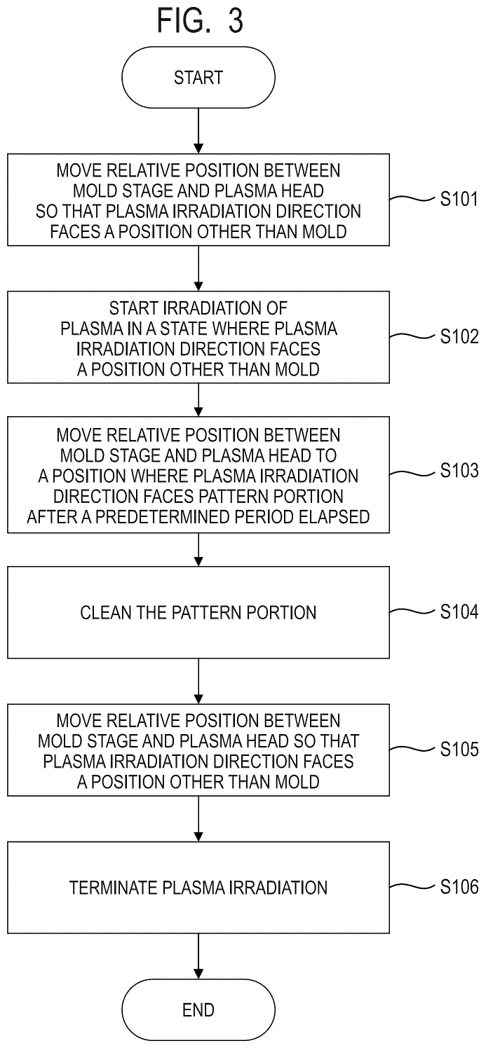

The cleaning method of the present embodiment will be described in order with reference to the flowchart of FIG. 3.

The controlling unit (not shown) moves (changes) the relative position between the mold stage 21 and the plasma irradiating portion 13 so that the plasma irradiation direction of the plasma irradiating portion 13 faces a position other than the mold 1 (step S101, pre-irradiation step).

Irradiation of the plasma 8 by the plasma irradiating portion 13 is started in a state where the plasma irradiation direction of the plasma irradiating portion 13 faces a position other than the mold 1 (step S102, irradiation start step).

Wait for a certain period to elapse from the start of the irradiation of the plasma 8 by the plasma irradiating portion 13. In a state in which the plasma 8 is being irradiated, at least one of the mold stage 21 and the plasma head 4 is moved in the XY plane by the driving unit so that the pattern portion 6 and the plasma irradiating portion 13 overlap each other in the XY plane. That is, the relative position between the mold stage 21 and the plasma head 4 is changed to a position so that the plasma irradiation direction faces the pattern portion 6 (step S103, moving step).

Cleaning of the pattern portion 6 of the mold 1 is performed by irradiating the plasma 8 in a state where the plasma irradiation direction faces the pattern portion 6 (step S104, irradiation step).

By starting cleaning of the mold 1 by this method, particles can be prevented from adhering to the pattern portion 6 because the plasma head 4 is not positioned below the pattern portion 6 at the start of irradiation of the plasma 8 in which many particles are generated.

When the necessary cleaning is completed, the relative position between the mold stage 21 and the plasma irradiating portion 13 is moved by the driving unit (not shown) so that the plasma irradiation direction of the plasma irradiating portion 13 faces a position other than the mold 1 while continuing the plasma irradiation (step S105, retraction step).

The irradiation of the plasma 8 by the plasma irradiating portion 13 is stopped in a state where the plasma irradiation direction of the plasma irradiating portion 13 is moved to a state of being facing a position other than the mold 1 (for example, a state of being facing the mold stage 21) (step S106, irradiation termination step).

As described above, in the present embodiment, in step S101, after a certain period has elapsed from the start of the irradiation of the plasma 8, the pattern portion 6 and the plasma head 4 are moved to positions facing each other, and cleaning is started. On the other hand, the cleaning may be started by detecting the particles released from the plasma head 4 and moving the pattern portion 6 and the plasma head 4 so as to face each other after the detected amount of the particles becomes equal to or less than the threshold value. In this case, a port for collecting particles may be provided in the vicinity of the plasma head 4, and the number of particles in the plasma 8 may be measured by a particle counter through the port.

According to the present embodiment, it is possible to efficiently remove foreign matter such as the imprint material deposited on the mold 1 without causing particles generated at the start of the irradiation of the plasma 8 to adhere to the pattern portion 6 of the mold 1.

### Second Embodiment

Next, a second embodiment will be described. In the second embodiment, a description of a configuration similar to that of the first embodiment will be omitted, and a different configuration will be described.

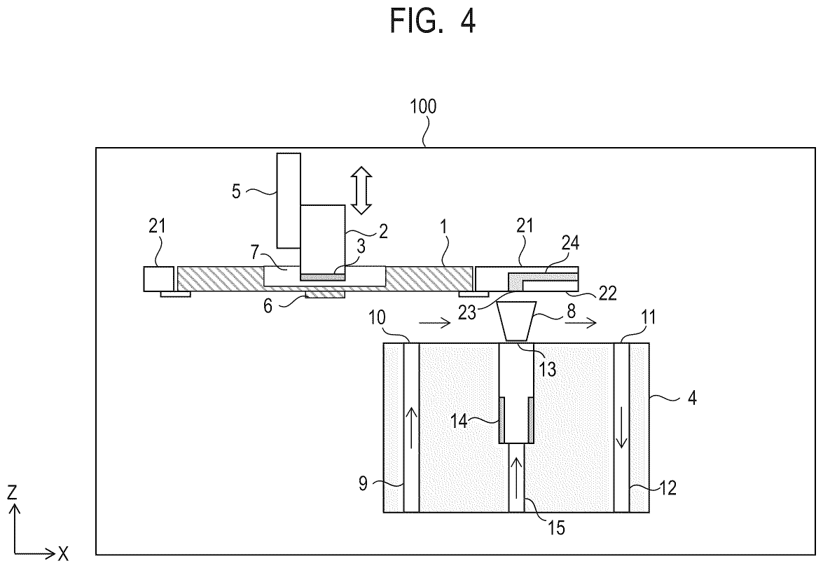

FIG. 4 is a schematic diagram illustrating a configuration of a cleaning apparatus 100 according to a second embodiment. The cleaning apparatus 100 according to the second embodiment includes an exhaust opening 23 connected to an exhaust unit (not shown) for exhausting and recovering particles on a lower surface 22 of the mold stage 21 that holds the mold 1.

The relative positions of the plasma head 4 and the mold stage 21 are adjusted by the illustrated controlling unit so that the plasma head 4 faces the exhaust opening 23 of the lower surface 22 of the mold stage 21 at the start of the irradiation of the plasma 8. The irradiation of the plasma 8 is started in a state where the plasma head 4 faces the exhaust opening 23, and the particles generated at the start of the irradiation of the plasma 8 are not diffused to the surroundings and can be recovered by the airflow passing through the exhaust flow path 24.

After a certain period has elapsed since the start of the irradiation of the plasma 8, at least one of the mold stage 21 and the plasma head 4 is moved in the XY plane while the plasma 8 is being irradiated, and the pattern portion 6 of the mold 1 is cleaned.

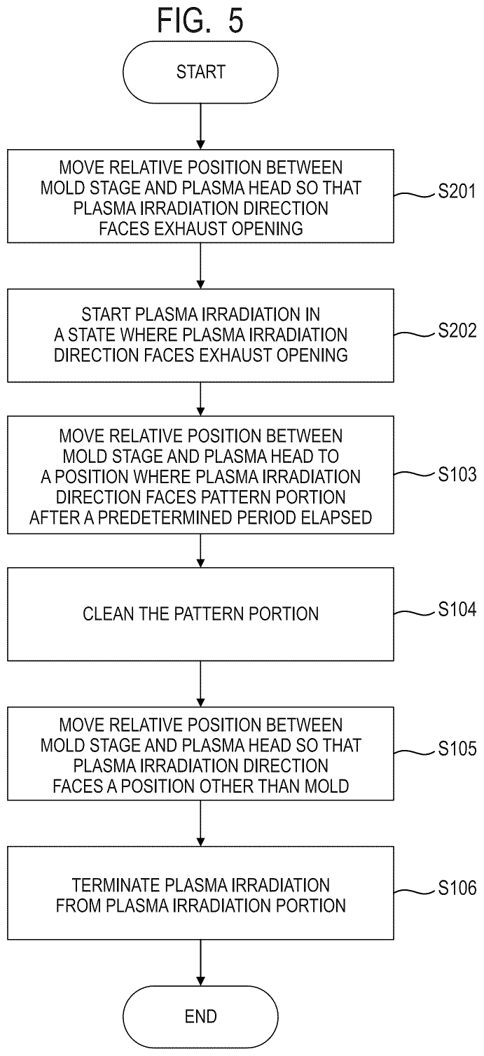

The cleaning method of the present embodiment will be described in order with reference to the flowchart of FIG. 5.

The controlling unit (not shown) moves (changes) the relative position between the mold stage 21 and the plasma irradiating portion 13 so that the plasma irradiation direction of the plasma irradiating portion 13 faces the exhaust opening 23 formed in the lower surface 22 of the mold stage 21 (step S201, pre-irradiation step).

In a state where the plasma irradiation direction of the plasma irradiating portion 13 faces the exhaust opening 23, irradiation of the plasma 8 by the plasma irradiating portion 13 is started (step S202, irradiation start step).

Steps S103 to S106 of the flowchart of FIG. 5 are the same as those of the first embodiment described with reference to FIG. 3, and a description thereof will be omitted here.

Also in the second embodiment, in step S201, after a predetermined time has elapsed since the start of the irradiation of the plasma 8, the pattern portion 6 and the plasma head 4 are moved to positions facing each other, and cleaning is started. On the other hand, similarly to the first embodiment, the cleaning may be started by detecting the particles released from the plasma head 4 and moving the pattern portion 6 and the plasma head 4 so as to face each other after the detected amount of the particles becomes equal to or less than a threshold value.

In the second embodiment, a branch (not shown) for collecting particles may be provided in the flow path of the exhaust flow path 24, and the number of particles may be measured by a particle counter (detecting unit) (not shown) provided at a destination of the branch. With this configuration, when the irradiation of the plasma 8 is started, the cleaning may be started by moving to the cleaning position after the number of particles (detection result) in the particle counter becomes equal to or less than the threshold value.

Only one exhaust opening 23 may be provided in the mold stage 21, or a plurality of exhaust openings 23 may be provided in the mold stage 21. Further, the position where the exhaust opening is provided may be a position other than the mold 1 (other than the original), and only the exhaust opening may be independently provided at a position where the irradiation direction is not directed to the mold stage 21, other members, or the mold 1. In the case where a plurality of exhaust openings 23 are provided, after the mold 1 is placed on the mold stage 21, the relative position of the mold stage 21 and the exhaust opening 23 may be moved to a state in which the exhaust opening 23 closest to the plasma irradiating portion 13 is located above the plasma irradiating portion 13, and irradiation of the plasma 8 may be started. As a result, it is possible to shorten the time until the cleaning is started.

In order to be able to collect the particles generated at the end of the irradiation of the plasma 8, the irradiation of the plasma 8 may be terminated after the relative position of the exhaust opening 23 and the plasma irradiating portion 13 is changed so that the exhaust opening 23 is located above the plasma irradiating portion 13. Further, a second exhaust opening (not shown) may be provided on the opposite side of the mold 1 with respect to the exhaust opening 23 used at the start of plasma irradiation.

Accordingly, in a case where the cleaning is finished with the plasma irradiating portion 13 being positioned on the opposite side to the exhaust opening 23 with the pattern portion 6 interposed therebetween, the movement is performed so that the second exhaust opening is located above the plasma irradiating portion 13, and then the irradiation of the plasma 8 can be terminated. By providing the second exhaust opening, the plasma irradiating portion 13 can be moved relatively to the position of the exhaust opening quickly regardless of the position of the plasma irradiating portion 13 at the end of cleaning, and particles generated at the end of the irradiation of plasma 8 can be recovered.

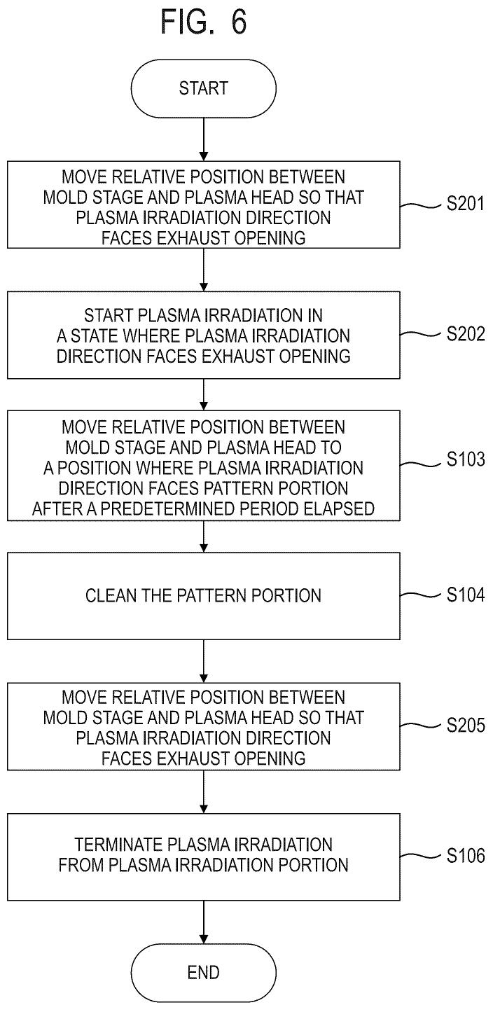

FIG. 6 shows a process flow in a case where the irradiation of plasma 8 is terminated after the movement is performed so that the exhaust opening is positioned above the plasma irradiating portion 13 in the second embodiment. In the flowchart, steps S201, S202, S103, and S104 are the same as those in FIG. 5, and thus description thereof is omitted.

When the necessary cleaning is completed in step S104, the relative position between the mold stage 21 and the plasma irradiating portion 13 is moved by the driving unit (not shown) so that the plasma irradiation direction of the plasma irradiating portion 13 faces the exhaust opening while continuing the plasma irradiation (step S205, retraction step). Here, the exhaust opening may be the exhaust opening 23 which faces the plasma irradiating portion 13 at the start of plasma irradiation, the second exhaust opening, or another exhaust opening.

Since step S106 of the flowchart of FIG. 6 is the same as that of the first embodiment described with reference to FIG. 3, a description thereof will be omitted here.

According to the present embodiment, the foreign matter such as the imprint material deposited on the mold 1 can be efficiently removed without causing the particles generated at the start of the irradiation of plasma 8 and the particles generated at the end of the irradiation to adhere to the pattern portion 6 of the mold 1, the lower surface 22 of the mold stage 21, and the upper surface of the plasma head 4.

### <Embodiment of Imprint Apparatus>

As an application example of the present invention, the cleaning apparatus 100 may be provided in an imprint apparatus.

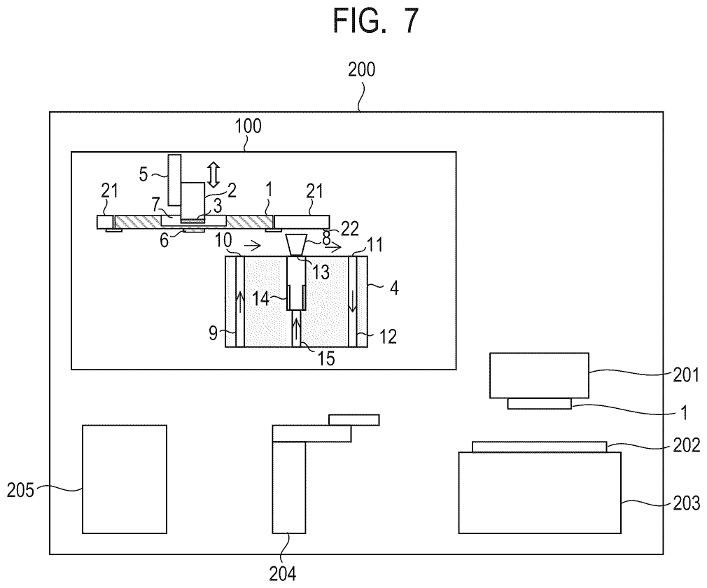

FIG. 7 is a schematic diagram illustrating a configuration of an imprint apparatus 200 to which the cleaning apparatus 100 is applied. The imprint apparatus 200 is an apparatus that forms a pattern of an imprint material on a substrate 202 using a mold 1. The imprint apparatus 200 includes a mold holding unit 201 configured to hold and move the mold 1, a substrate stage 203 configured to hold and move the substrate 202, a transporting unit 204 configured to transport the mold 1, a recovery unit 205, and the cleaning apparatus 100.

The recovery unit 205 recovers a gas generated through the cleaning of the mold 1 by the cleaning apparatus 100, particularly, a gas that hinders the imprint process. However, the recovery unit 205 is not necessarily a necessary constituent element in a case where the gas that hinders the imprint process is not generated or in a case where the cleaning apparatus 100 is used independently of the imprint apparatus 200.

The configuration of the cleaning apparatus 100 according to the present embodiment is the same as that of the above-described embodiment. In addition, if there is a place where a plurality of molds 1 are stored in the imprint apparatus 200 and cleaning is possible in the place, the imprint processing may be performed using another mold in parallel with cleaning of the mold 1.

By providing the cleaning apparatus 100 in the imprint apparatus 200, the distance by which the mold 1 is conveyed to the cleaning apparatus 100 can be shortened, and thus the cleaning processing time can be shortened.

### <Embodiments of Manufacturing Methods>

A method of manufacturing a device (a semiconductor integrated circuit element, a liquid crystal display element, or the like) as an article includes a step of forming a pattern on a substrate 202 (a wafer, a glass plate, or a film-like substrate) using the imprint apparatus 200 described above.

The manufacturing method may further include etching the patterned substrate 202.

When another article such as a patterned medium (recording medium) or an optical element is manufactured, the manufacturing method may include another process of processing the substrate 202 on which a pattern is formed instead of etching.

The method of manufacturing an article according to the present embodiment is advantageous in at least one of performance, quality, productivity, and production cost of the article as compared with the conventional method.

### Other Embodiments

Although preferred embodiments of the present invention have been described above, the present invention is not limited to these embodiments, and various modifications and changes can be made within the scope of the gist of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-216686, filed Dec. 22, 2023, which is hereby incorporated by reference herein in its entirety.

What is claimed is:

1. A cleaning apparatus for cleaning an original with plasma, comprising:
a stage for holding the original;
a plasma irradiating portion for irradiating plasma;
a driving unit for adjusting a relative position of the stage and the plasma irradiating portion; and
a controlling unit configured to control the plasma irradiating portion and the driving unit to start an irradiation of the plasma when a pattern portion included in the original and the plasma irradiating portion do not face each other.

2. The cleaning apparatus according to claim 1, wherein the controlling unit controls the driving unit so that the original and the plasma irradiating portion face each other in a state where the plasma is irradiated after the irradiation of the plasma is started, to clean the original.

3. The cleaning apparatus according to claim 1, wherein the controlling unit controls the driving unit so that the pattern portion and the plasma irradiating portion face each other in a state where the plasma is irradiated after the irradiation of the plasma is started, to clean the original.

4. The cleaning apparatus according to claim 1, comprising an exhaust opening,
wherein the controlling unit controls a starting of the irradiation of the plasma when the exhaust opening and the plasma irradiating portion face each other.

5. The cleaning apparatus according to claim 1, wherein the controlling unit controls the plasma irradiating portion and the driving unit to terminate the irradiation of the plasma in a state where the pattern portion and the plasma irradiating portion do not face each other.

6. The cleaning apparatus according to claim 1, comprising an exhaust opening,
wherein the controlling unit terminates the irradiation of the plasma in a state where the exhaust opening and the plasma irradiating portion face each other.

7. The cleaning apparatus according to claim 4, wherein the exhaust opening is disposed in the stage.

8. The cleaning apparatus according to claim 4, comprising a plurality of the exhaust openings.

9. The cleaning apparatus according to claim 1, wherein a position at which the irradiation of the plasma is started and a position at which the irradiation of the plasma is terminated are different from each other.

10. The cleaning apparatus according to claim 1, comprising a detecting unit for detecting particles,
wherein the controlling unit controls the driving unit based on a detection result of the detecting unit.

11. The cleaning apparatus according to claim 10,
wherein the detecting unit is a particle counter that detects a number of particles in the plasma,
wherein, when the number of particles detected by the detecting unit is less than a threshold, the controlling unit controls the driving unit so that the pattern portion and the plasma irradiating portion face each other.

12. An imprint apparatus comprising a cleaning apparatus for cleaning an original with plasma, the cleaning apparatus comprising:
a stage for holding the original;
a plasma irradiating portion for irradiating plasma;
a driving unit for adjusting a relative position of the stage and the plasma irradiating portion; and
a controlling unit configured to control the plasma irradiating portion and the driving unit to start an irradiation of the plasma when a pattern portion included in the original and the plasma irradiating portion do not face each other,
wherein the original and a resin on the substrate are brought into contact with each other to form a pattern on the resin.

13. A method of manufacturing an article comprising:
a forming step of forming a pattern on a substrate by using an imprint apparatus, and
a processing step of processing the substrate on which the pattern is formed in the forming step,
wherein the imprint apparatus comprises a cleaning apparatus for cleaning an original with plasma, the cleaning apparatus comprising:
a stage for holding the original;
a plasma irradiating portion for irradiating plasma;
a driving unit for adjusting a relative position of the stage and the plasma irradiating portion; and
a controlling unit configured to control the plasma irradiating portion and the driving unit to start irradiation of the plasma when a pattern portion included in the original and the plasma irradiating portion do not face each other,
wherein the original and a resin on the substrate are brought into contact with each other to form a pattern on the resin,
wherein an article is manufactured by using the substrate processed in the processing step.

14. A cleaning method for cleaning an original with plasma, comprising:
a pre-irradiation step of adjusting a relative position of the original and a plasma irradiating portion for irradiating plasma so that a pattern portion included in the original and the plasma irradiating portion do not face each other;
an irradiation start step of starting an irradiation of the plasma after the pre-irradiation step;
a movement step of adjusting a relative position of the original and the plasma irradiating portion so that the pattern portion and the plasma irradiating portion face each other in a state where the plasma is irradiated after the irradiation start step; and
an irradiation step of cleaning the original by irradiating the original with the plasma after the moving step.

15. The cleaning method according to claim 14, further comprising:
a retraction step of adjusting a relative position between the original and the plasma irradiating portion for irradiating plasma so that the pattern portion and the plasma irradiating portion do not face each other in a state where the plasma is irradiated after the irradiation step,
an irradiation termination step of terminating the irradiation of the plasma after the retraction step.
